(19) United States
(12) Patent Application Publication
(10) Pub. No.: US 2025/0240929 A1
(43) Pub. Date: Jul. 24, 2025

(54) LIQUID COOLING SYSTEM AND SERVER

(71) Applicant: SHENZHEN ENVICOOL TECHNOLOGY CO., LTD., Shenzhen (CN)

(72) Inventors: Xiaoxin XU, Shenzhen (CN); Xiaolei AI, Shenzhen (CN)

(73) Assignee: SHENZHEN ENVICOOL TECHNOLOGY CO., LTD., Shenzhen (CN)

(21) Appl. No.: 18/814,628

(22) Filed: Aug. 26, 2024

(30) Foreign Application Priority Data
Jan. 19, 2024 (CN) 202420143466.6

(51) Int. Cl. H05K 7/20; G01M 3/16; G01M 3/18

(52) U.S. Cl. CPC H05K 7/20772; H05K 7/20272; G01M 3/165; G01M 3/182; G01M 3/186

(57) ABSTRACT

The present application provides a liquid cooling system including a water distribution-collection device, multiple liquid cooling bodies and multiple first liquid guide tubes. One end of each first liquid guide tube is communicated with at least one corresponding liquid cooling body, and the other end of the first liquid guide tube is connected to a port of the water distribution-collection device through a corresponding cut-off assembly. The cut-off assembly includes a first connection device and a second connection device that are detachable and separable from each other. The first connection device is arranged at a tube mouth of the first liquid guide tube and is configured to block the corresponding first liquid guide tube when being disassembled from the second connection device. The second connection device is arranged at the port and is configured to block the corresponding port when being disassembled from the first connection device.

### CROSS REFERENCE TO RELATED APPLICATIONS

The present application claims priority to Chinese Patent Application No. 202420143466.6, titled “LIQUID COOLING SYSTEM AND SERVER”, filed on Jan. 19, 2024 with the China National Intellectual Property Administration, which is incorporated herein by reference in its entirety.

### FIELD OF THE INVENTION

The present application relates to the technical field of heat dissipation, and in particular to a liquid cooling system and a server.

### BACKGROUND

With the increase of the power density of servers, there is a high requirement for heat dissipation. Compared with the air cooling heat exchange, the liquid cooling heat exchange can provide higher heat exchange efficiency to meet heat exchange requirements of servers. At present, the liquid cooling for servers mainly adopts cold plate liquid cooling, also known as a liquid cooling plate. The liquid cooling plate exchanges heat with a high heat-generating element of a server, and then quickly transfers heat to the outside of the server by being connected to a heat exchange device through a liquid guide tube.

During the operation of the server, a liquid cooling system may leak due to fatigue, vibration, or any other reason. If an electronic device of the server is in contact with a leaking high-pressure liquid, a fault such as a short circuit may occur. Therefore, it is necessary to detect whether there is a leak in the liquid cooling system, and shut down and repair in time when a leak is detected. However, the entire system is required to be disassembled for maintenance when a leak is detected in the liquid cooling system, which is costly and inefficient.

### SUMMARY

In view of the above, the object of the present application is to provide a liquid cooling system and a server, which are structured to allow a group of the liquid guide tube and the liquid cooling body that are in communication to be disassembled and repaired separately when the liquid cooling body or the liquid guide tube of the liquid cooling system leaks. Thus, there is no need to disassemble the entire liquid cooling system, thereby reducing costs and improving efficiency.

In order to achieve the above object, the present application provides the following technical solutions.

A liquid cooling system includes a water distribution-collection device, multiple liquid cooling bodies for exchanging heat with a heating element, and multiple first liquid guide tubes. One end of each of the multiple first liquid guide tubes is communicated with at least one corresponding liquid cooling body, and the other end of the first liquid guide tube is communicated with a port of the water distribution-collection device through a corresponding cut-off assembly. The cut-off assembly includes a first connection device and a second connection device that are detachable and separable from each other. The first connection device is arranged at a tube mouth of the first liquid guide tube and is configured to block the first liquid guide tube when being disassembled from the second connection device, and the second connection device is arranged at the port and is configured to block the port when being disassembled from the first connection device.

In an embodiment, in the liquid cooling system, at least one column of the liquid cooling bodies are provided along an arrangement direction of ports of the water distribution-collection device, and the liquid cooling bodies in at least one column are communicated with different ports of the water distribution-collection device through corresponding first liquid guide tubes.

In an embodiment, in the liquid cooling system, multiple columns of the liquid cooling bodies are arranged along the arrangement direction of the ports of the water distribution-collection device, and the multiple columns of the liquid cooling bodies are located on the same side of the water distribution-collection device.

In an embodiment, in the liquid cooling system, the liquid cooling bodies in any one of at least two columns are arranged side by side with the respective liquid cooling bodies of another of the at least two columns, and the liquid cooling bodies arranged side by side are connected in parallel through a second liquid guide tube.

In an embodiment, in the liquid cooling system, the liquid cooling bodies in at least one column are connected in series through a third liquid guide tube, and two liquid cooling bodies at a head end and a tail end are respectively communicated with corresponding ports of the water distribution-collection device through a liquid inflow tube and a liquid outflow tube of a corresponding first liquid guide tube.

In an embodiment, the liquid cooling system includes multiple liquid cooling bodies connected in parallel, which are configured to exchange heat with a graphics processor, and multiple liquid cooling bodies connected in series, which are configured to exchange heat with a switch element.

In an embodiment, the liquid cooling system further includes a detection device for detecting liquid leakage of the liquid cooling body and/or the first liquid guide tube, and the first connection device and the second connection device are disassembled when the detection device detects liquid leakage.

In an embodiment, in the liquid cooling system, the detection device includes two detection wires arranged in a disconnected manner, and each of the two detection wires is provided with a detection piece that extends towards and is spaced apart from the other of the two detection wires, the detection pieces on the two detection wires in each group are alternately distributed at a preset interval.

In an embodiment, in the liquid cooling system, each of the first connection device and the second connection device includes a connection seat and a valve core. A flow channel is provided in the connection seat, and a toggle head is provided on the connection seat. The valve core is slidably arranged in the connection seat, and the valve core is provided with a through hole and a groove. The toggle head of the first connection device is configured to be inserted into the groove of the second connection device, and the toggle head of the second connection device is configured to be inserted into the groove of the first connection device. The two toggle heads drive the two valve cores to slide when the first connection device and the second connection device slide relative to each other, so that the two through holes are synchronously aligned with the respective flow channels for opening or staggered with the respective flow channels for blocking; and the two toggle heads are engaged with the corresponding connection seats when the two toggle heads drive the two valve cores to slide to a blocking position.

The liquid cooling system according to the present application includes a water distribution-collection device, multiple liquid cooling bodies, and multiple first liquid guide tubes. The multiple liquid cooling bodies are configured to exchange heat with a heating element. One end of each of the multiple first liquid guide tubes is communicated with at least one corresponding liquid cooling body, and the other end of the first liquid guide tube is communicated with a port of the water distribution-collection device through a corresponding cut-off assembly. The cut-off assembly includes a first connection device and a second connection device that are detachable and separable from each other. The first connection device is arranged at a tube mouth of the first liquid guide tube and is configured to block the corresponding first liquid guide tube when the first connection device is disassembled from the second connection device. The second connection device is arranged at the port and is configured to block the port when the second connection device is disassembled from the first connection device.

In the liquid cooling system according to the present application, the first liquid guide tube is connected to the corresponding port of the water distribution-collection device through the cut-off assembly. If any first liquid guide tube leaks, the first connection device and the second connection device of the cut-off assembly connected between the leaked first liquid guide tube and the corresponding port are disassembled and separated. If any liquid cooling body leaks, the first connection device and the second connection device of the cut-off assembly between the first liquid guide tube in communication with the liquid cooling body and the corresponding port are disassembled and separated. After separation, the first connection device blocks the tube mouth of the first liquid guide tube to prevent leakage of liquid from the first liquid guide tube and the first liquid cooling body connected to the first liquid guide tube. Moreover, after separation, the second connection device blocks the corresponding port of the water distribution-collection device to prevent leakage of liquid from the water distribution-collection device. In summary, according to the liquid cooling system of the present application, when leakage occurs, the first liquid guide tube and the liquid cooling body that are in communication and correspond to the leakage position can be removed from the liquid cooling system as a maintenance unit and then repaired. There is no need to disassemble the entire liquid cooling system, which reduces the maintenance cost and improves the maintenance efficiency.

In order to achieve the above object, a server is further provided according to the present application, which includes the liquid cooling system described above. Since the liquid cooling system has the above technical effects, the server including the liquid cooling system also has the corresponding technical effects.

### BRIEF DESCRIPTION OF THE DRAWING

In order to more clearly illustrate the technical solutions in the embodiments of the present application or in the conventional technology, the following will briefly introduce drawings required in the description of the embodiments or the conventional technology. Apparently, the drawings in the following description are only some of the embodiments of the present application. For those skilled in the art, other drawings can also be obtained based on these drawings without creative efforts.

FIG. 1 is a schematic structural view of a liquid cooling system according to an embodiment of the present application;

FIG. 2 is a schematic top view of FIG. 1; and

FIG. 3 is a schematic structural view of a detection device.

The reference signs in the figures are listed as follows:

| | |
|---|---|
| liquid cooling body 1, | water distribution-collection device 2, |
| first liquid guide tube 3, | cut-off assembly 4, |
| second liquid guide tube 5, | third liquid guide tube 6, |
| detection device 7; | |
| liquid inflow tube 31, | liquid outflow tube 32; |
| first connection device 41, | second connection device 42; |
| detection wire 71, | detection piece 72. |

### DETAIL DESCRIPTION OF EMBODIMENTS

A liquid cooling system and a server are disclosed according to the embodiments of the present application. The liquid guide tube and the liquid cooling body of the liquid cooling system, which are communicated with each other, are defined as a group. When a liquid cooling body or a liquid guide tube leaks, the group including the leaked liquid guide tube or the leaked liquid cooling body can be separately disassembled as a maintenance unit. Thus, there is no need to disassemble the liquid cooling system as a whole, thereby reducing costs and improving efficiency.

The technical solutions in the embodiments of the present application are clearly and completely described below in conjunction with the drawings. Apparently, the described embodiments are only part of the embodiments of the present application, not all of the embodiments of the present application. Any other embodiment obtained by those skilled in the art based on the embodiments in the present application without creative efforts shall fall within the protection scope of the present application.

The liquid cooling system according to the present application includes a liquid cooling body, a first liquid guide tube, and a water distribution-collection device. The liquid cooling body is generally a liquid cooling plate, but in some cases may be of a block structure or any other structure. The liquid cooling body is configured to exchange heat with a heating element of an electronic device such as a server. It can be understood that the heating element may include an element such as a processor that generates heat itself during operation, and an element that is heated indirectly by absorbing heat generated by the self-heat generating element. The liquid cooling body has at least surface to be heated, which is configured to abut against an electronic element to be cooled. In this way, the heated surface of the liquid cooling body and a heat dissipation surface of the electronic element are in thermal contact.

In the present application, the water distribution-collection device may be of a multi-channel structure, which includes a water distributor and a water collector. It can be understood that the water distributor and the water collector may be separately provided, or may be integrated into one piece.

In the present application, one end of the first liquid guide tube is communicated with a corresponding liquid cooling body, and the other end of the first liquid guide is connected to a corresponding port of the water distribution-collection device. The first liquid guide tube is configured to discharge a high-temperature liquid out of the liquid cooling body and introduce a low-temperature liquid into the liquid cooling body. It should be noted that the liquid in the liquid cooling body and the liquid guide tube in the present application may be cooling water or refrigerant. The cooling water includes, but is not limited to, water or a mixture of water, e.g., anti-freezing cooling water added with ethylene glycol. The refrigerant includes, but is not limited to, a refrigerant added with fluorine. The first liquid guide tube has a liquid inflow channel and a liquid outflow channel for liquid circulation, so as to allow the high-temperature liquid in the liquid cooling body to flow out and the low-temperature liquid to flow into the liquid cooling body. It can be understood that the guide tube may include a liquid inflow tube and a liquid outflow tube arranged separately, or may include a multi-cavity tube that is integrally arranged and has different cavities configured for inflow and outflow of liquid.

In the present application, a corresponding structure is provided to facilitate separate repair at the leakage location for the possible leakage of the liquid cooling body or the liquid guide tube. In the following embodiments, the above structure will be described, and other structures of the liquid cooling system may refer to the conventional technology, which is not repeated here.

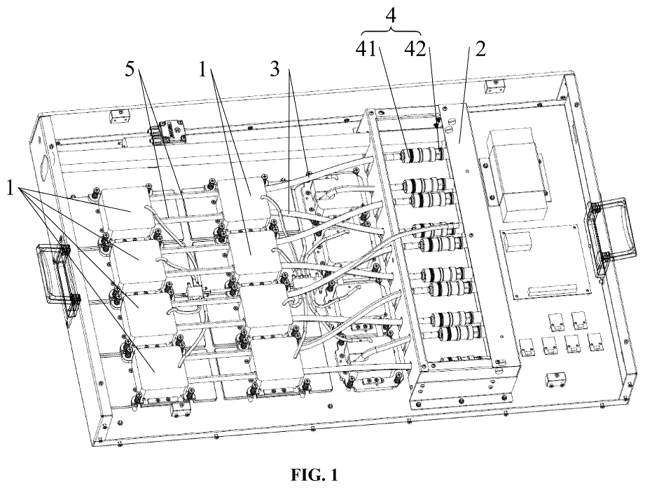

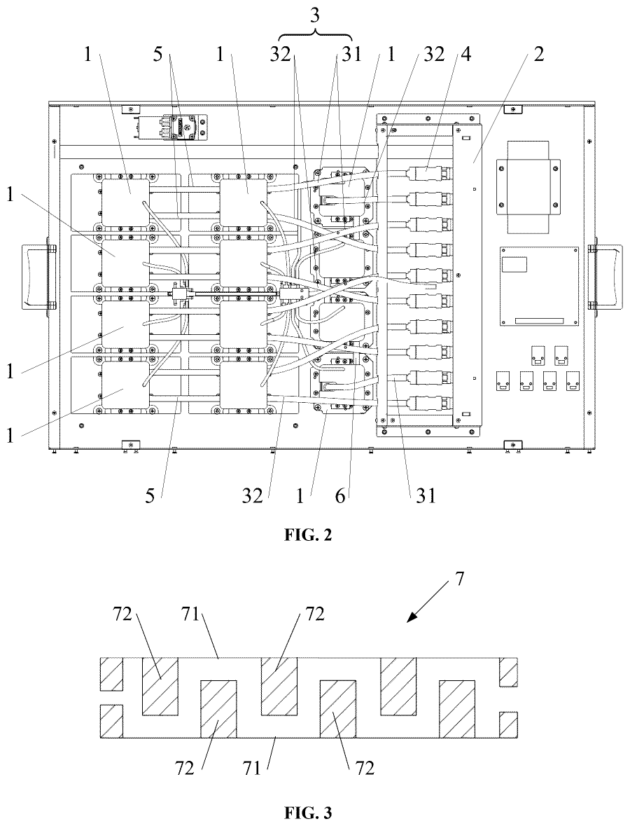

In an embodiment, referring to FIGS. 1 to 2, the liquid cooling system according to the present application includes a water distribution-collection device 2, multiple liquid cooling bodies 1, and multiple first liquid guide tubes 3. Each liquid cooling body 1 is configured to exchange heat with a heating element. One end of each first liquid guide tube 3 is communicated with at least one corresponding liquid cooling body 1, and the other end of the first liquid guide tube 3 is connected to a port of the water distribution-collection device 2 via a corresponding cut-off assembly 4. Different from the conventional technology that the first liquid guide tube is directly connected to the corresponding port of the water distribution-collection device 2, in the present application, the cut-off assembly 4 is arranged between the first liquid guide tube and the water distribution-collection device 2. The cut-off assembly 4 includes a first connection device 41 and a second connection device 42 that can be detachably separated from each other. The first connection device 41 is arranged at a tube mouth of the corresponding first liquid guide tube 3 and blocks the first liquid guide tube 3 when the first connection device 41 is disassembled from the second connection device 42. The second connection device 42 is arranged at the corresponding port and blocks the port when the second connection device 42 is disassembled from the first connection device 41. That is, in normal operation, the first connection device 41 is connected to the second connection device 42, and the first liquid guide tube 3 is communicated with the corresponding port. When leakage occurs and maintenance is required, the cut-off assembly 4 is disconnected, that is, the first connection device 41 is separated from the second connection device 42, so that the first liquid guide tube 3 is separated from the corresponding port accordingly. In the separated state, the first connection device 41 blocks the first liquid guide tube 3, and the second connection device 42 blocks the corresponding port, thereby preventing liquid leakage.

In the liquid cooling system according to the present application, the first liquid guide tube 3 is connected to the corresponding port of the water distribution-collection device 2 through the cut-off assembly 4. If any first liquid guide tube 3 leaks, the first connection device 41 and the second connection device 42 in the cut-off assembly 4 connected between the leaked first liquid guide tube 3 and the corresponding port are disassembled and separated. If any liquid cooling body 1 leaks, the first connection device 41 and the second connection device 42 in the cut-off assembly 4 between the first liquid guide tube 3 in communication with the liquid cooling body 1 and the corresponding port are disassembled and separated. After separation, the first connection device 41 blocks the tube mouth of the first liquid guide tube 3 to prevent liquid in the first liquid guide tube 3 and the first liquid cooling body 1 connected to the first liquid guide tube 3 from leaking. Moreover, after separation, the second connection device 42 blocks the corresponding port of the water distribution-collection device 2 to prevent liquid in the water distribution-collection device 2 from leaking. In summary, according to the liquid cooling system of the present application, when leakage occurs, the first liquid guide tube 3 and the liquid cooling body 1 that are in communication and correspond to the leakage position can be removed from the liquid cooling system as a maintenance unit and then repaired. There is no need to disassemble the entire liquid cooling system, thereby reducing maintenance costs and improving maintenance efficiency.

In some embodiments, the first liquid guide tube 3 includes a first liquid inflow tube and a first liquid outflow tube which are separately provided, and the first liquid inflow tube and the first liquid outflow tube are respectively communicated with a first outlet and a first inlet of the water distribution-collection device 2 through corresponding cut-off assemblies 4. When disassembling, the cut-off assembly 4 between the first liquid inflow tube and the first outlet and the cut-off assembly 4 between the first liquid outflow tube and the first inlet are disconnected. In other embodiments, the first liquid guide tube 3 is a multi-cavity tube, and a set of cut-off assemblies 4 may be arranged between the multi-cavity tube and the corresponding ports.

In some embodiments, at least one column of liquid cooling bodies 1 are provided along an arrangement direction of the ports of the water distribution-collection device 2. The liquid cooling bodies 1 in the at least one column are communicated with different ports of the water distribution-collection device 2 through corresponding first liquid guide tubes 3. Arranging multiple liquid cooling bodies 1 along the arrangement direction of the ports is conductive to shortening the length of the first liquid guide tube 3 and facilitating the arrangement of the first liquid guide tubes 3. For example, at least part of the first liquid guide tubes 3 are arranged in parallel, reducing the mutual influence of the arrangement of the first liquid guide tubes 3.

In some embodiments, multiple columns of liquid cooling bodies 1 are arranged along the arrangement direction of the ports of the water distribution-collection device 2. The multiple columns of liquid cooling bodies 1 are provided to improve the heat dissipation efficiency. The liquid cooling bodies 1 may be arranged relative to the first liquid guide tubes 3 as needed. It should be noted that the term “multiple columns” described in the present application refers to two or more columns.

Further, the multiple columns of liquid cooling bodies 1 are located on the same side of the water distribution-collection device 2. Disposing the multiple columns of liquid cooling bodies 1 on the same side of the water distribution-collection device 2 facilitates the arrangement of the first liquid guide tubes 3. Even if there is a leak, the possible leak location is relatively small, which is convenient for maintenance. In other embodiments, the liquid cooling bodies 1 may also be arranged on different sides of the water distribution-collection device 2, for example, according to the layout requirements of the heating elements.

In some embodiments, the liquid cooling bodies 1 in the at least two columns are arranged side by side. The side-by-side arrangement may be carried out in a direction perpendicular to the arrangement direction of the ports of the water distribution-collection device 2, and the liquid cooling bodies 1 in any one of the at least two columns are distributed in a line. For example, as shown in FIG. 2, there are two columns of liquid cooling bodies 1 at the left of this figure, and the connecting lines of the liquid cooling bodies 1 from top to bottom are parallel. In a case that three columns of liquid cooling bodies 1 are provided, the corresponding liquid cooling bodies 1 of the three columns at the same level are collinear, and the corresponding liquid cooling bodies 1 of the three columns from top to bottom are parallel. In the embodiments, all of the liquid cooling bodies 1 in at least two columns are distributed in an array of multiple rows and columns. The array distribution structure is compact and has high space utilization. The possible leakage area formed by the liquid cooling bodies 1 distributed in the array is regular, with little mutual shielding and influence or even no mutual shielding, which is convenient for individual maintenance.

In some embodiments, the liquid cooling bodies 1 distributed side by side are connected in parallel through a second liquid guide tube 5. That is, by the second liquid guide tube 5, the liquid cooling bodies 1 distributed side by side are connected in parallel to the corresponding first liquid guide tube 3. A detection unit is formed by a first liquid guide tube 3, the liquid cooling bodies 1 that are connected in parallel to the first liquid guide tube 3, and the corresponding second liquid guide tube 5. When leakage occurs from at least one of the first liquid guide tube 3, the liquid cooling bodies 1 that are connected in parallel to the first liquid guide tube 3, and the second liquid guide tube 5 for connecting the liquid cooling bodied 1 in parallel, the unit is disassembled as a whole for maintenance. That is, the cut-off assembly 4 between the first liquid guide tube 3 and the corresponding port is disconnected. For a high heat-generating element, multiple liquid cooling bodies 1 that are connected in parallel may be provided, that is, the first liquid guide tube 3 provides cold liquid directly or indirectly via the second liquid guide tube 5 to the liquid cooling bodies 1 that are connected in parallel. In this way, each liquid cooling body 1 has high heat exchange efficiency.

In some embodiments, at least one column of liquid cooling bodies 1 are connected in series through a third liquid guide tube 6, and two liquid cooling bodies 1 at a head end and a tail end are respectively connected to corresponding ports through a liquid inflow tube 31 and a liquid outflow tube 32 of the first liquid guide tube 3. That is, the first liquid guide tube 3 communicated with the liquid cooling bodies 1 connected in series includes a liquid inflow tube 31 and a liquid outflow tube 32 separately arranged. The liquid inflow tube 31 is connected to a corresponding port through a cut-off assembly 4, and the liquid outflow tube 32 is connected to a corresponding port through a cut-off assembly 4. A detection unit is formed by the liquid inflow tube 31, the liquid outflow tube 32, the third liquid guide tube 6, and the liquid cooling bodies 1 that are connected in series between the liquid inflow tube 31 and the liquid outflow tube 32. When leakage occurs from at least one of the liquid inflow tube 31, the liquid outflow tube 32, the liquid cooling bodies 1 that are connected in series between the liquid inflow tube 31 and the liquid outflow tube 32, and the third liquid guide tube 6 for connecting the liquid cooling bodies 1 in series, the unit is disassembled as a whole for maintenance. That is, the cut-off assembly 4 between the liquid inflow tube 31 and the corresponding port and the cut-off assembly 4 between the liquid outflow tube 32 and the corresponding port are disconnected. For a low heat-generating element, multiple liquid cooling bodies 1 connected in series may be provided, and the liquid sequentially flows through the liquid cooling bodies 1 connected in series to take away the heat of the low heat-generating element, thereby meeting the heat dissipation requirements, simplifying the pipeline structure, and reducing energy consumption.

In some embodiments, the liquid cooling bodies 1 distributed in an array of multiple rows and columns are arranged on the same side of the water distribution-collection device 2, and at least one column of liquid cooling bodies 1 are connected in series through the third liquid guide tube 6, and at least two columns of the liquid cooling bodies 1 distributed side by side are connected in parallel through the second liquid guide tube 5. As arranged above, the overall heat dissipation area is gridded, and the comprehensive performance of the liquid cooling system is optimized by fully utilizing the high heat dissipation efficiency of the parallel-connected liquid cooling bodies 1 and the low energy consumption of the series-connected liquid cooling bodies 1. It is convenient to arrange the first liquid guide tubes 3, the second liquid guide tubes 5, and the third liquid guide tubes 6. For example, the second liquid guide tubes 5 are distributed in parallel; the third liquid guide tubes 6 are distributed in parallel; and the first liquid guide tubes 3 are distributed in parallel.

There is given an example in which one column of liquid cooling bodies 1 are connected in series, and the other columns of liquid cooling bodies 1 are connected in parallel, and each first liquid guide tube 3 includes a liquid inflow tube 31 and a liquid outflow tube 32. In order to facilitate the arrangement of the first liquid guide tubes 3, the liquid inflow tube 31 communicated with a first row of the parallel-connected liquid cooling bodies 1 is communicated with an outlet of a first row on the water distribution-collection device 2, and the liquid inflow tubes 31 communicated with the other rows of the parallel-connected liquid cooling bodies 1 are respectively connected to outlets of the various rows on the water distribution-collection device 2; the liquid cooling body 1 of the first row in the column of the series-connected liquid cooling bodies 1 is communicated with the liquid outflow tube 32 and is communicated with an inlet of the first row on the water distribution-collection device 2, and the liquid cooling body 1 of the last row in the column of the series-connected liquid cooling bodies 1 is communicated with the liquid inflow tube 31 and is communicated with an outlet of the last row on the water distribution-collection device 2; the liquid outflow tube 32 communicated with the first row of the parallel-connected liquid cooling bodies 1 is communicated with an inlet of a second row on the water distribution-collection device 2, and the liquid outflow tubes 32 communicated with the other rows of the parallel-connected liquid cooling bodies 1 are respectively communicated with inlets of the various rows on the water distribution-collection device 2. Through the above arrangement, the first liquid cooling piping is arranged with short lines; line winding is not easy to occur; and mutual influence between lines is reduced.

In some embodiments, multiple parallel-connected liquid cooling bodies 1 are configured to exchange heat with a graphics processor, and multiple series-connected liquid cooling bodies 1 are configured to exchange heat with a switch element. The graphics processor generates a large amount of heat and is cooled by the multiple liquid cooling bodies 1 connected in parallel, improving the heat dissipation efficiency and ensuring the reliable operation of the graphics processor. The switch element generates less heat and is cooled by the multiple liquid cooling bodies 1 connected in series, thereby meeting the heat dissipation requirements with the low energy consumption.

In some embodiments, the liquid cooling system further includes a detection device 7 for detecting leakage of the liquid cooling body 1 and/or the first liquid guide tube 3. When the detection device 7 detects a leakage, the first connection device 41 and the second connection device 42 are disassembled. By providing the detection device 7, the first connection device 41 and the second connection device 42 are connected when no leakage is detected, and are disassembled and separated when leakage is detected, so as to repair the separated detection unit independently. The above arrangement facilitates timely detection of liquid leakage and adoption of appropriate measures. The detection device 7 may be a conventional detection structure such as a liquid sensor or a detection tape for detecting liquid leakage, which is not specifically limited here. In other embodiments, visual inspection may be possible, and the first connection device 41 and the second connection device 42 at the corresponding position are disassembled when liquid leakage is observed.

In some embodiments, referring to FIG. 3, the detection device 7 includes two detection wires 71 arranged in a disconnected manner. Each of the two detection wires 71 is provided with a detection piece 72 that extends towards and is spaced apart from the other of the two detection wires 71. It can be understood that the detection pieces 72 are spaced apart, including that the detection pieces 72 on the two detection wires 71 do not contact with each other, and that the detection piece 72 on each of the two detection wires 71 does not contact the other of the two detection wires 71. During the detection, the leakage can be detected when the leaking liquid contacts two detection pieces 72 at the same time, or contacts a detection piece 72 on one of the two detection wires 71 and the other of the two detection wires 71 at the same time, or contacts the two detection wires 71 at the same time. By provision of the detection piece 72, a spacing distance between the two detection wires 71 may be increased to increase a detection area, and the detection accuracy may be ensured by setting the spacing distance between the detection pieces 72. The smaller the distance between the detection piece 72 and the detection wire 71, the higher the detection accuracy.

Further, the detection pieces 72 on the two detection wires 71 are alternately distributed at preset intervals. In an embodiment, the detection pieces 72 on each detection wire 71 are distributed in a comb shape, and the width of the detection piece 72 on each detection wire 71 may be greater than, less than, or equal to half of the spacing distance between the two detection wires 71. It should be noted that the detection piece 72 shown in FIG. 3 has a rectangular cross section, or may has any other cross section, e.g., a triangle cross section, a trapezoid cross section, an L-shaped cross section, or a T-shaped cross section. The detection piece 72 is only required to be of a structure that protrudes from one of the two detection wires 71 toward the other of the two detection wires 71.

In some embodiments, each of the first connection device 41 and the second connection device 42 includes a connection seat and a valve core. A flow channel is provided in the connection seat and a toggle head is provided on the connection seat. The valve core is slidably arranged in the connection seat, and the valve core is provided with a through hole and a groove. The toggle head on the connection seat of the first connection device 41 is configured to be inserted into the groove of the valve core of the second connection device 42, and the toggle head on the connection seat of the second connection device 42 is configured to be inserted into the groove of the valve core of the first connection device 41. The first connection device 41 and the second connection device 42 slide relative to each other, so that the two through holes can be synchronously aligned with the corresponding flow channels so as to open the first and second connection devices 41, 42, or staggered with each other so as to block the first and second connection devices 41, 42. When the two toggle heads drive the two valve cores to slide to a blocking position, the two toggle heads are engaged with the corresponding connection seats. Specifically, the two toggle heads drive the two valve cores to slide, so that the through hole of the valve core of the first connection device 41 and the flow channel of the connection seat of the first connection device 41 are aligned with each other to open the first connection device 41, and the through hole of the valve core of the second connection device 42 and the flow channel of the connection seat of the second connection device 42 are aligned with each other to open the second connection device 42. The flow channel of the first connection device 41 and the flow channel of the second connection device 42 are aligned with each other, and the first connection device 41 is communicated with the second connection device 42. The toggle head on the first connection device 41 is engaged with the connection seat of the second connection device 42, and the toggle head on the second connection device 42 is engaged with the connection seat of the first connection device 41, so as to realize the connection between the first connection device 41 and the second connection device 42. When the first connection device 41 and the second connection device 42 slide in opposite directions, the two toggle heads drive the two valve cores to slide, so that to the through hole of the valve core of the first connection device 41 and the flow channel of the connection seat of the first connection device 41 are staggered with each other to close the first connection device 41, and the through hole of the valve core of the second connection device 42 and the flow channel of the connection seat of the second connection device 42 are staggered with each other to close the second connection device 42. The toggle head on the first connection device 41 can be pulled out from the second connection device 42, and the toggle head on the second connection device 42 can be pulled out from the first connection device 41, thereby realizing disassembly and separation. In other embodiments, the valve core may be rotatably arranged on the connection seat, and the toggle head drives the valve core to rotate so as to open or close the connection devices.

In other embodiments, the first connection device 41 and the second connection device 42 may be of a conventional quick-release structure. Alternatively, each of the first connection device 41 and the second connection device 42 may include a cut-off valve, and two cut-off valves are detachably connected, for example, directly or via a pipeline. Alternatively, the cut-off valve may be integrated into a quick-release joint, so that quick disassembly and assembly can be realized and individual sealing after disassembly can be realized.

Based on the liquid cooling system provided in the above embodiments, a server is further provided according to the present application, which includes any liquid cooling system described above. Since the server includes the liquid cooling system described above, it brings about the similar beneficial effects as described in the above embodiments.

The embodiments in the specification are described in a progressive manner, and each embodiment focuses on the difference from other embodiments. Same and similar parts in each embodiment may be referred to each other.

The above description of the embodiments is provided to enable those skilled in the art to implement or use the present application. Various modifications to the embodiments are apparent to those skilled in the art. General principles defined herein may be implemented in other embodiments without departing from spirits or scopes of the present application. Therefore, the present application is not limited to the embodiments shown herein, but is to be accorded the widest scope consistent with the principles and novel features disclosed herein.

1. A liquid cooling system comprising a water distribution-collection device, a plurality of liquid cooling bodies for heat exchange with a heating element, and a plurality of first liquid guide tubes, wherein
each of the plurality of first liquid guide tubes has an end communicated with at least one corresponding liquid cooling body, and the other end communicated with a port of the water distribution-collection device through a corresponding cut-off assembly; and
the cut-off assembly includes a first connection device and a second connection device that are detachable and separable from each other, and
the first connection device is arranged at a tube mouth of the first liquid guide tube and is configured to block the first liquid guide tube when being disassembled from the second connection device, and the second connection device is arranged at the port and is configured to block the port when being disassembled from the first connection device.

2. The liquid cooling system according to claim 1, wherein at least one column of the liquid cooling bodies are provided along an arrangement direction of the ports of the water distribution-collection device, and the liquid cooling bodies in at least one column are communicated with different ports of the water distribution-collection device through the corresponding first liquid guide tubes.

3. The liquid cooling system according to claim 2, wherein a plurality of columns of the liquid cooling bodies are arranged along the arrangement direction of the ports of the water distribution-collection device, and are located on the same side of the water distribution-collection device.

4. The liquid cooling system according to claim 3, wherein the liquid cooling bodies in any one of at least two columns are arranged side by side with the respective liquid cooling bodies of another of the at least two columns, and the liquid cooling bodies arranged side by side are connected in parallel through a second liquid guide tube.

5. The liquid cooling system according to claim 3, wherein the liquid cooling bodies in at least one column are connected in series through a third liquid guide tube, and two liquid cooling bodies at a head end and a tail end are respectively communicated with corresponding ports of the water distribution-collection device through a liquid inflow tube and a liquid outflow tube of a corresponding first liquid guide tube.

6. The liquid cooling system according to claim 3, comprising
a plurality of the liquid cooling bodies connected in parallel and configured to exchange heat with a graphics processor, and
a plurality of the liquid cooling bodies connected in series and configured to exchange heat with a switch element.

7. The liquid cooling system according to claim 1, further comprising a detection device for detecting liquid leakage of the liquid cooling body and/or the first liquid guide tube, wherein the first connection device and the second connection device are disassembled when the detection device detects liquid leakage.

8. The liquid cooling system according to claim 7, wherein the detection device comprises two detection wires arranged in a disconnected manner, and each of the two detection wires is provided with a detection piece that extends towards and is spaced apart from the other of the two detection wires, the detection pieces on the two detection wires in each group are alternately distributed at a preset interval.

9. The liquid cooling system according to claim 1, wherein each of the first connection device and the second connection device includes a connection seat and a valve core,
a flow channel is provided in the connection seat, and a toggle head is provided on the connection seat;
the valve core is slidably arranged in the connection seat, and the valve core is provided with a through hole and a groove,
the toggle head of the first connection device is configured to be inserted into the groove of the second connection device, the toggle head of the second connection device is configured to be inserted into the groove of the first connection device; and
the two toggle heads drive the two valve cores to slide when the first connection device and the second connection device slide relative to each other, so that the two through holes are synchronously aligned or staggered with the respective flow channels for opening or blocking; and the two toggle heads are engaged with the corresponding connection seats when the two toggle heads drive the two valve cores to slide to a blocking position.

10. The liquid cooling system according to claim 2, further comprising a detection device for detecting liquid leakage of the liquid cooling body and/or the first liquid guide tube, wherein the first connection device and the second connection device are disassembled when the detection device detects liquid leakage.

11. The liquid cooling system according to claim 3, further comprising a detection device for detecting liquid leakage of the liquid cooling body and/or the first liquid guide tube, wherein the first connection device and the second connection device are disassembled when the detection device detects liquid leakage.

12. The liquid cooling system according to claim 4, further comprising a detection device for detecting liquid leakage of the liquid cooling body and/or the first liquid guide tube, wherein the first connection device and the second connection device are disassembled when the detection device detects liquid leakage.

13. The liquid cooling system according to claim 5, further comprising a detection device for detecting liquid leakage of the liquid cooling body and/or the first liquid guide tube, wherein the first connection device and the second connection device are disassembled when the detection device detects liquid leakage.

14. The liquid cooling system according to claim 2, wherein each of the first connection device and the second connection device includes a connection seat and a valve core,
a flow channel is provided in the connection seat, and a toggle head is provided on the connection seat;
the valve core is slidably arranged in the connection seat, and the valve core is provided with a through hole and a groove,
the toggle head of the first connection device is configured to be inserted into the groove of the second connection device, the toggle head of the second connection device is configured to be inserted into the groove of the first connection device; and
the two toggle heads drive the two valve cores to slide when the first connection device and the second connection device slide relative to each other, so that the two through holes are synchronously aligned or staggered with the respective flow channels for opening or blocking; and the two toggle heads are engaged with the corresponding connection seats when the two toggle heads drive the two valve cores to slide to a blocking position.

15. The liquid cooling system according to claim 3, wherein each of the first connection device and the second connection device includes a connection seat and a valve core,
a flow channel is provided in the connection seat, and a toggle head is provided on the connection seat;
the valve core is slidably arranged in the connection seat, and the valve core is provided with a through hole and a groove,
the toggle head of the first connection device is configured to be inserted into the groove of the second connection device, the toggle head of the second connection device is configured to be inserted into the groove of the first connection device; and
the two toggle heads drive the two valve cores to slide when the first connection device and the second connection device slide relative to each other, so that the two through holes are synchronously aligned or staggered with the respective flow channels for opening or blocking; and the two toggle heads are engaged with the corresponding connection seats when the two toggle heads drive the two valve cores to slide to a blocking position.

16. The liquid cooling system according to claim 4, wherein each of the first connection device and the second connection device includes a connection seat and a valve core,
a flow channel is provided in the connection seat, and a toggle head is provided on the connection seat;
the valve core is slidably arranged in the connection seat, and the valve core is provided with a through hole and a groove,
the toggle head of the first connection device is configured to be inserted into the groove of the second connection device, the toggle head of the second connection device is configured to be inserted into the groove of the first connection device; and
the two toggle heads drive the two valve cores to slide when the first connection device and the second connection device slide relative to each other, so that the two through holes are synchronously aligned or staggered with the respective flow channels for opening or blocking; and the two toggle heads are engaged with the corresponding connection seats when the two toggle heads drive the two valve cores to slide to a blocking position.

17. The liquid cooling system according to claim 5, wherein each of the first connection device and the second connection device includes a connection seat and a valve core,
a flow channel is provided in the connection seat, and a toggle head is provided on the connection seat;
the valve core is slidably arranged in the connection seat, and the valve core is provided with a through hole and a groove,
the toggle head of the first connection device is configured to be inserted into the groove of the second connection device, the toggle head of the second connection device is configured to be inserted into the groove of the first connection device; and
the two toggle heads drive the two valve cores to slide when the first connection device and the second connection device slide relative to each other, so that the two through holes are synchronously aligned or staggered with the respective flow channels for opening or blocking; and the two toggle heads are engaged with the corresponding connection seats when the two toggle heads drive the two valve cores to slide to a blocking position.

18. A server, comprising the liquid cooling system according to claim 1.
